(19) United States
(12) Patent Application Publication
(10) Pub. No.: US 2008/0124923 A1
(43) Pub. Date: May 29, 2008

(54) Fabricating Method of Semiconductor Device

(76) Inventor: DONG KI JEON, Gangneung-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/929,819

(22) Filed: Oct. 30, 2007

(30) Foreign Application Priority Data
Nov. 24, 2006 (KR) 10-2006-0116775

(51) Int. Cl. H01L 21/443

(52) U.S. Cl. 438/664; 257/E21.478

(57) ABSTRACT

Disclosed is a method of fabricating a semiconductor device, capable of improving the reliability of a semiconductor device. The method of fabricating the semiconductor device comprises forming a cobalt layer on an entire surface of a semiconductor substrate including a transistor structure, forming a cobalt nitride layer on the cobalt layer, performing a first rapid thermal processing to form CoSi, removing a non-reactive cobalt layer and a non-reactive cobalt nitride layer, and performing a second rapid thermal processing to form CoSi₂.

### CROSS REFERENCE TO RELATED APPLICATION

The present application claims the benefit under 35 U.S.C. §119 of Korean Patent Application No. 10-2006-0116775, filed Nov. 24, 2006, which is hereby incorporated by reference in its entirety.

### BACKGROUND

In a method of fabricating a semiconductor device, silicide, which is a compound of silicon with metal, is often formed to electrically connect a gate electrode and a source/a drain with a metal line.

Cobalt (Co) is generally employed for the above described silicide in the semiconductor device when fabricating a semiconductor device in a technology node of less than a 0.18 μm technology node. In addition, the cobalt is prepared in the form of CoSi₂ to provide the superior electrical contact behavior between a metal line and a gate electrode or a source/drain.

Further, since the cobalt for the electrical contact has a strong reactivity, the cobalt is easily oxidized in atmosphere. In order to prevent the cobalt from being oxidized, a titanium nitride layer, which does not directly react with the cobalt, is capped on the cobalt to aid in properly forming the silicide.

The titanium nitride effectively prevents the cobalt from making contact with other gas in the normal temperature, which is room temperature of 15˜25° C. However, the titanium nitride has a columnar structure in which grains of the titanium nitride are aligned in the longitudinal direction in the high temperature, so fine gaps are formed. This allows various gases, such as oxygen, to make contact with the cobalt through the fine gaps, causing the performance degradation of the semiconductor device.

Thus there exists a need in the art for an improved semiconductor device and fabrication method thereof.

### BRIEF SUMMARY

Embodiments of the present invention provide a method of fabricating a semiconductor device.

A method of fabricating a semiconductor device according to an embodiment comprises forming a cobalt layer on an entire surface of a semiconductor substrate including a transistor structure, forming a cobalt nitride layer on the cobalt layer, forming CoSi (a compound of silicon with cobalt) through a first rapid thermal processing, removing a non-reactive cobalt layer and a non-reactive cobalt nitride layer, and forming CoSi₂ through a second rapid thermal processing.

### BRIEF DESCRIPTION OF THE DRAWING

FIGS. 1 to 5 are views representing a process of fabricating a semiconductor device according to an embodiment of the present invention.

### DETAILED DESCRIPTION

Hereinafter, embodiments will be described in detail with reference to the accompanying drawings. First, it should be noted that identical elements or parts have been designated by the same reference numbers in the drawings. In the description of the embodiment, the detailed description of related known functions or constructions will be omitted herein to avoid making the subject matter of the embodiment ambiguous.

In addition, in the description of embodiments, it will be understood that when a layer (or film), a region, a pad, a pattern or a structure are referred to as being ‘on/above/over/upper’ another layer, region, pad, pattern or substrate, it can be directly on another layer, region, pad, pattern or substrate, or one or more intervening layers, regions, pads, patterns or structures may also be present. Further, it will be understood that when a layer (or film), a region, a pad, a pattern or a structure are referred to as being ‘down/below/under/lower’ another layer, region, pad, pattern or substrate, it can be directly under layer, region, pad, pattern or substrate, or one or more intervening layers, regions, pads, patterns or structures may also be present. In addition, it will also be understood that when a layer (or film), a region, a pad, a pattern or a structure are referred to as being ‘between’ two layers, two regions, two pads, two patterns or two structures, it can be the only layer, region, pad, pattern or structure between the two layers, the two regions, the two pads, the two patterns and the two structures or one or more intervening layers, regions, pads, patterns or structures may also be present. Thus, the meaning thereof must be determined based on the scope of the present invention.

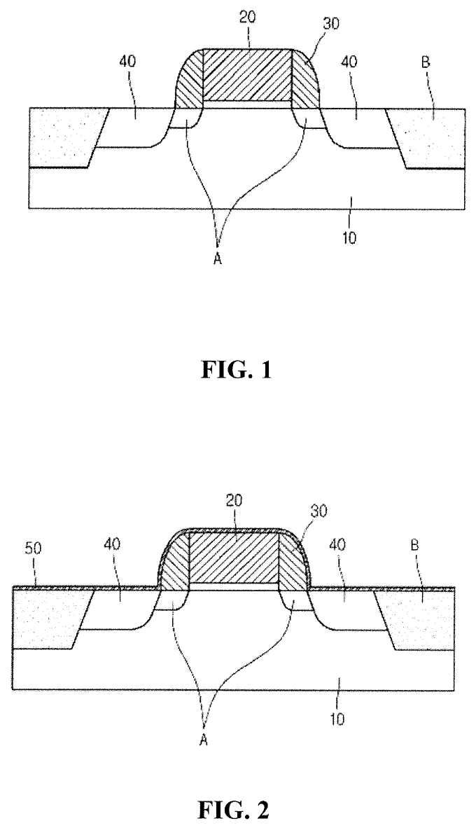

Referring to FIG. 1, a transistor structure can be formed on a semiconductor substrate. The transistor structure can be isolated using isolation regions B. In one embodiment, a surface of a semiconductor substrate including silicon can be oxidized to form a gate oxide layer thereon, and a polysilicon layer can be deposited on the gate oxide layer. The polysilicon layer can be formed on the gate oxide layer through, for example, a chemical vapor deposition (CVD) process.

Then, a photoresist film can be coated on the polysilicon layer, and a pattern for the photoresist can be transferred to the photoresist at a reduced scale. The photoresist can be exposed and developed to form a photoresist pattern in a predetermined region. The polysilicon and the gate oxide layer can be dry-etched through, for example, a Reactive Ion Etching (RIE) using the photoresist pattern as a mask to form a polysilicon pattern 20 and a gate oxide layer pattern.

Then, the photoresist pattern is removed, and low-density dopants can be implanted onto an entire surface of the semiconductor substrate 10 using the gate structure including the polysilicon pattern 20 and the gate oxide layer pattern as a mask for ion implantation to form lightly doped source/drain (LDD) regions A. Then, a spacer 30 can be formed on sidewalls of the gate structure.

Then, high-density dopants can be implanted onto the semiconductor substrate 10 using the gate structure and the spacer 30 as an ion implant mask. A thermal diffusion process can be performed, thereby forming source/drain regions 40.

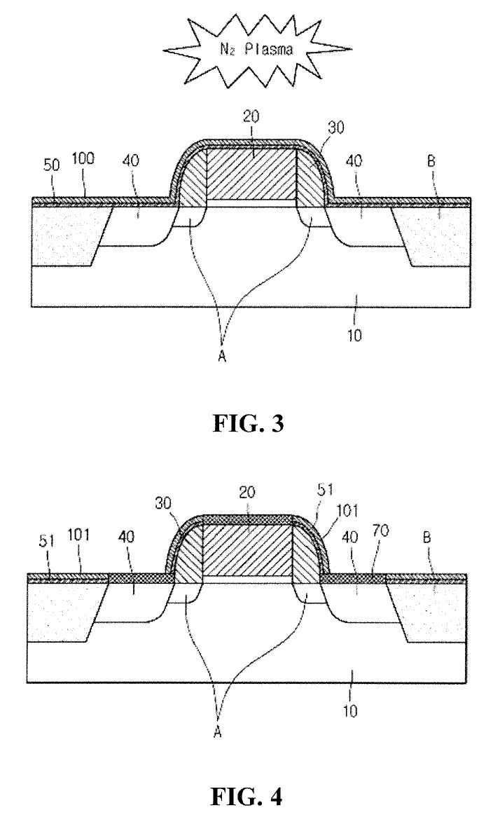

Referring to FIG. 2, a cobalt layer 50 can be formed on the entire surface of the semiconductor substrate 10 including the transistor structure in a thickness of about 100 Å by depositing cobalt. Referring to FIG. 3, a cobalt nitride layer (CoN₂) 100 can be formed on a surface of the cobalt layer 50 through a plasma nitridization process.

If the cobalt nitride layer 100 is too thick, the sheet resistance of a cobalt silicide layer (CoSi₂) to be formed later is increased, so the thickness of the cobalt nitride layer 100 can be properly adjusted.

Accordingly, in order to inhibit the cobalt layer 50 from being oxidized during a subsequent process and inhibit the sheet resistance of the cobalt silicide layer from being increased, the cobalt nitride layer 100 can be formed in a thickness of about 50 Å to about 300 Å.

In the nitrogen plasma process used for forming the cobalt nitride layer 100, a ratio of nitrogen to hydrogen can be adjusted in order to form the cobalt nitride layer 100 having high efficiency. In this case, nitrogen and hydrogen are preferably fed into a chamber for generating plasma in a ratio of 1:1 to 1:2. Most preferably, nitrogen and hydrogen are fed into the chamber in a ratio of 1:1.5. After nitrogen and hydrogen are fed into the chamber at a selected ratio as described above, the plasma nitridization process can be performed under conditions of an RF (Radio Frequency) Power of 500 W to 1000 W, temperature of 200° C. to 500° C., and pressure of 1 Torr to 3 Torr.

In this case, a plasma supplier (showerhead) should be spaced apart from the semiconductor substrate 10 by a distance of 1 cm to 4 cm. If the distance is less than 1 cm, reflected RF Power may be increased, so that the plasma nitridization efficiency is lowered. In addition, if the distance is more than 4 cm, the plasma nitridization efficiency may be lowered.

Referring to FIG. 4, a first rapid thermal processing (RTP) can be performed so as to form CoSi 70, which is compound of silicon with cobalt, on upper surfaces of the source/drain regions 40 and the gate electrode 20. Then, a non-reactive cobalt layer 51 and a non-reactive cobalt nitride layer 101 are removed. For instance, the non-reactive cobalt 51 and the non-reactive cobalt nitride layer 101 can be selectively removed through a wet etching process.

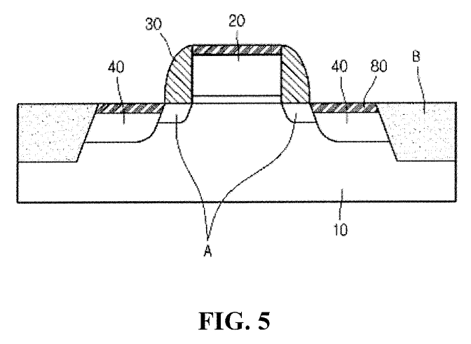

Then, referring to FIG. 5, a second rapid thermal processing can be performed to form the cobalt silicide (CoSi₂) 80.

As described above, according to the related art, a capping titanium nitride layer is formed on the cobalt layer. The reason for forming the capping titanium nitride layer is that the cobalt is very easily oxidized due to the strong reactivity. In order to prevent the cobalt layer from being oxidized, the titanium layer nitride layer which does not directly react with the cobalt layer is capped, so that silicide can be properly formed.

The titanium nitride has a superior function of preventing the cobalt from making contact with other gases at a normal temperature. However, the titanium nitride is prepared in the form of columnar structure in which grains thereof are elongated at a high temperature, so fine gaps may become formed and gases, such as oxygen, make contact with the cobalt through the gaps, thereby causing the performance degradation in the semiconductor device.

According to embodiments of the present invention, the cobalt nitride layer is formed on the cobalt layer through a plasma nitridization process. Since the cobalt nitride layer has a dense structure at a high temperature as well as at normal temperature, the oxidation of the cobalt layer under the cobalt nitride layer is effectively inhibited.

Accordingly, the device defect, which may occur during the manufacturing process of the semiconductor device, can be inhibited in advance, and the reliability of the semiconductor device is improved.

In addition, the defect rate of the semiconductor device is reduced, so that the yield rate of products is enhanced and the manufacturing cost of the semiconductor device is reduced.

While the method of fabricating the semiconductor device according to the present embodiment has been described with reference to the accompanying drawings, it will be apparent to those skilled in the art that various modifications and variations can be made in the present invention. Thus, it is intended that the present invention covers the modifications and variations of this invention provided they come within the scope of the appended claims and their equivalents.

According to the method of fabricating the semiconductor device of the embodiment, the defect of the semiconductor device is effectively avoided in advance by inhibiting the cobalt layer from being oxidized during the manufacturing process of the semiconductor device, so that the yield rate of products is improved, and the reliability of the semiconductor device is improved while reducing the manufacturing cost.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the princibles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device, comprising:
forming a cobalt layer on an entire surface of a semiconductor substrate including a transistor structure;
forming a cobalt nitride layer on the cobalt layer;
forming CoSi through a first rapid thermal processing;
removing a non-reactive cobalt layer and a non-reactive cobalt nitride layer; and
forming CoSi2 through a second rapid thermal processing.

2. The method according to claim 1, wherein the cobalt nitride layer has a thickness of about 50 Å to about 300 Å.

3. The method according to claim 1, wherein forming the cobalt nitride layer comprises performing a plasma nitridization process.

4. The method according to claim 3, wherein nitrogen and hydrogen are fed at a ratio of 1:1 to 1:2 into a chamber for generating plasma.

5. The method according to claim 3, wherein nitrogen and hydrogen are fed at a ratio of 1:1.5 into a chamber for generating plasma.

6. The method according to claim 3, wherein the nitridization process is performed under conditions of an RF (Radio Frequency) power of 500 W to 1000 W, a temperature of 200° C. to 500° C. and a pressure of 1 Torr to 3 Torr.

7. The method according to claim 3, wherein a plasma supplier providing the plasma is spaced apart from the semiconductor substrate by a distance of 1 cm to 4 cm.
